(19) United States
(12) Patent Application Publication
(10) Pub. No.: US 2025/0301781 A1
(43) Pub. Date: Sep. 25, 2025

(54) WALL ISOLATION FOR BULK FORKSHEET DEVICE

(71) Applicant: International Business Machines Corporation, Armonk, NY (US)

(72) Inventors: Min Gyu Sung, Latham, NY (US); Julien Frougier, Albany, NY (US); Ruilong Xie, Niskayuna, NY (US); Juntao Li, Cohoes, NY (US); Chanro Park, Clifton Park, NY (US); Nicolas Jean Loubet, GUILDERLAND, NY (US); Tao Li, Slingerlands, NY (US)

(21) Appl. No.: 18/613,683

(22) Filed: Mar. 22, 2024

(51) Int. Cl. H01L 27/092; H01L 21/8238; H01L 29/06; H01L 29/423; H01L 29/49; H01L 29/66; H01L 29/775; H01L 29/786

(52) U.S. Cl. CPC H10D 84/85; H10D 30/014; H10D 30/031; H10D 30/43; H10D 30/6735; H10D 30/6739; H10D 30/6757; H10D 62/121; H10D 84/0177; H10D 84/038

(57) ABSTRACT

A microelectronic structure that includes a forksheet device that includes a first fin and a second fin and plurality of channel layers located above the first and second fin. A first liner located along each sidewall of the fin and a second liner located along the surface of the first liner. The first liner isolates the fin from electrically interacting with the second liner. A shallow trench isolation layer located adjacent to the second liner.

### BACKGROUND

The present invention generally relates to the field of microelectronics, and more particularly to forming a wall isolation for forksheet devices.

Nanosheet is the lead device architecture in continuing CMOS scaling. However, nanosheet technology has shown issues when scaling down such that as the devices become smaller and closer together, they are interfering with each other. During the formation of forksheet devices it has become necessary to isolate the different components to prevent the formation of defects forming during the processing stages.

### BRIEF SUMMARY

Additional aspects and/or advantages will be set forth in part in the description which follows and, in part, will be apparent from the description, or may be learned by practice of the invention.

A microelectronic structure that includes a forksheet device that includes a first fin and a second fin and plurality of channel layers located above the first and second fins. A first liner located along each sidewall of the first and second fin and a second liner located along the surface of the first liner. The first liner isolates the first and second from electrically interacting with the second liner. A shallow trench isolation layer located adjacent to the second liner.

A microelectronic structure that includes a forksheet device that includes a first fin and a second fin and plurality of channel layers located above the first and second fins. A first liner located along each sidewall of the first and second fin and a second liner located along the surface of the first liner. The first liner isolates the first and second from electrically interacting with the second liner. A shallow trench isolation layer located adjacent to the second liner and the first liner and the second liner extends under a bottom surface of the shallow trench isolation layer.

A microelectronic structure that includes a forksheet device that includes a first fin 105F and a second fin and plurality of channel layers located above the first and second fins. A first liner located along each sidewall of the first and second fin. The first liner has a thickness in the range of about 2 to 5 nanometers. A second liner located along the surface of the first liner. The second liner has a thickness in the range of about 2 to 8 nanometers. The first liner isolates the first and second fin from electrically interacting with the second liner. A shallow trench isolation layer located adjacent to the second liner. A shallow trench isolation layer located adjacent to the second liner and the first liner and the second liner extends under a bottom surface of the shallow trench isolation layer.

### BRIEF DESCRIPTION OF THE DRAWINGS

The above and other aspects, features, and advantages of certain exemplary embodiments of the present invention will be more apparent from the following description taken in conjunction with the accompanying drawings, in which:

FIG. 1 illustrates a cross section of the forksheet device after initial processing to form the fins, in accordance with the embodiment of the present invention.

FIG. 2 illustrates a cross section of the forksheet device after formation of the first liner, in accordance with the embodiment of the present invention.

FIG. 3 illustrates a cross section of the forksheet device after formation of the second liner, in accordance with the embodiment of the present invention.

FIG. 4 illustrates a cross section of the forksheet device after formation of the shallow trench isolation layer, in accordance with the embodiment of the present invention.

FIG. 5 illustrates a cross section of the forksheet device after removal of excess materials, in accordance with the embodiment of the present invention.

FIG. 6 illustrates a cross section of the forksheet device after pulling down of the shallow trench isolation layer, in accordance with the embodiment of the present invention.

FIG. 7 illustrates a cross section of the forksheet device after pulling down of the second liner and the removal of the hardmask, in accordance with the embodiment of the present invention.

FIG. 8 illustrates a cross section of the forksheet device after pulling down of the first liner, in accordance with the embodiment of the present invention.

FIG. 9 illustrates a cross section of the forksheet device after removal of the sacrificial cap and the first and second sacrificial layers, and after a cleaning process that remove a portion of the first pillar liner, in accordance with the embodiment of the present invention.

FIG. 10 illustrates a cross section of the forksheet device after formation of a first and second work function metal, formation of the gate, and formation of an interlayer dielectric layer, in accordance with the embodiment of the present invention.

### DETAILED DESCRIPTION

The following description with reference to the accompanying drawings is provided to assist in a comprehensive understanding of exemplary embodiments of the invention as defined by the claims and their equivalents. It includes various specific details to assist in that understanding but these are to be regarded as merely exemplary. Accordingly, those of ordinary skill in the art will recognize that various changes and modifications of the embodiments described herein can be made without departing from the scope and spirit of the invention. In addition, descriptions of well-known functions and constructions may be omitted for clarity and conciseness.

The terms and the words used in the following description and the claims are not limited to the bibliographical meanings but are merely used to enable a clear and consistent understanding of the invention. Accordingly, it should be apparent to those skilled in the art that the following description of exemplary embodiments of the present invention is provided for illustration purpose only and not for the purpose of limiting the invention as defined by the appended claims and their equivalents.

It is understood that the singular forms “a,” “an,” and “the” include plural referents unless the context clearly dictates otherwise. Thus, for example, reference to “a component surface” includes reference to one or more of such surfaces unless the context clearly dictates otherwise.

Detailed embodiments of the claimed structures and the methods are disclosed herein: however, it can be understood that the disclosed embodiments are merely illustrative of the claimed structures and methods that may be embodied in various forms. This invention may, however, be embodied in many different forms and should not be construed as limited to the exemplary embodiments set forth herein. Rather, these exemplary embodiments are provided so that this disclosure will be thorough and complete and will fully convey the scope of this invention to those skilled in the art. In the description, details of well-known features and techniques may be omitted to avoid unnecessarily obscuring the present embodiments.

References in the specification to “one embodiment,” “an embodiment,” an example embodiment,” etc., indicate that the embodiment described may include a particular feature, structure, or characteristic, but every embodiment may not include the particular feature, structure, or characteristic. Moreover, such phrases are not necessarily referring to the same embodiment. Further, when a particular feature, structure, or characteristic is described in connection with an embodiment, it is submitted that it is within the knowledge of one of ordinary skill in the art to affect such feature, structure, or characteristic in connection with other embodiments whether or not explicitly described.

For purpose of the description hereinafter, the terms “upper,” “lower,” “right,” “left,” “vertical,” “horizontal,” “top,” “bottom,” and derivatives thereof shall relate to the disclosed structures and methods, as orientated in the drawing figures. The terms “overlying,” “atop,” “on top,” “positioned on,” or “positioned atop” mean that a first element, such as a first structure, is present on a second element, such as a second structure, where intervening elements, such as an interface structure may be present between the first element and the second element. The term “direct contact” means that a first element, such as a first structure, and a second element, such as a second structure, are connected without any intermediary conducting, insulating, or semiconductor layer at the interface of the two elements.

In the interest of not obscuring the presentation of embodiments of the present invention, in the following detailed description, some processing steps or operations that are known in the art may have been combined together for presentation and for illustrative purposes and in some instance may have not been described in detail. In other instances, some processing steps or operations that are known in the art may not be described at all. It should be understood that the following description is rather focused on the distinctive features or elements of various embodiments of the present invention.

Various embodiments of the present invention are described herein with reference to the related drawings. Alternative embodiments can be devised without departing from the scope of this invention. It is noted that various connections and positional relationships (e.g., over, below, adjacent, etc.) are set forth between elements in the following description and in the drawings. These connections and/or positional relationships, unless specified otherwise, can be direct or indirect, and the present invention is not intended to be limiting in this respect. Accordingly, a coupling of entities can refer to either a direct or indirect coupling, and a positional relationship between entities can be direct or indirect positional relationship. As an example of indirect positional relationship, references in the present description to forming layer “A” over layer “B” includes situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains,” or “containing” or any other variation thereof, are intended to cover a non-exclusive inclusion. For example, a composition, a mixture, process, method, article, or apparatus that comprises a list of elements is not necessarily limited to only those elements but can include other element not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiment or designs. The terms “at least one” and “one or more” can be understood to include any integer number greater than or equal to one, i.e., one, two, three, four, etc. The terms “a plurality” can be understood to include any integer number greater than or equal to two, i.e., two, three, four, five, etc. The term “connection” can include both indirect “connection” and a direct “connection.”

As used herein, the term “about” modifying the quantity of an ingredient, component, or reactant of the invention employed refers to variation in the numerical quantity that can occur, for example, through typical measuring and liquid handling procedures used for making concentrations or solutions. Furthermore, variation can occur from inadvertent error in measuring procedures, differences in manufacture, source, or purity of the ingredients employed to make the compositions or carry out the methods, and the like. The terms “about” or “substantially” are intended to include the degree of error associated with measurement of the particular quantity based upon the equipment available at the time of the filing of the application. For example, about can include a range of +8%, or 5%, or 2% of a given value. In another aspect, the term “about” means within 5% of the reported numerical value. In another aspect, the term “about” means within 10, 9, 8, 7, 6, 5, 4, 3, 2, or 1% of the reported numerical value.

Various processes are used to form a micro-chip that will be packaged into an integrated circuit (IC) fall in four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE), and more recently, atomic layer deposition (ALD) among others. Removal/etching is any process that removes material from the wafer. Examples include etching process (either wet or dry), reactive ion etching (RIE), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implant dopants. Films of both conductors (e.g., aluminum, copper, etc.) and insulators (e.g., various forms of silicon dioxide, silicon nitride, etc.) are used to connect and isolate electrical components. Selective doping of various regions of the semiconductor substrate allows the conductivity of the substrate to be changed with the application of voltage.

Reference will now be made in detail to the embodiments of the present invention, examples of which are illustrated in the accompanying drawings, where like reference numerals refer to like elements throughout. The present invention is directed towards forksheet devices that include a shaft (or fin) and prongs (or nanosheets). The fin can be enclosed by a shallow trench isolation layer or an oxide layer, for example, SiO₂. When forming the shallow trench isolation layer or oxide layer can cause defects within the fin that is comprised of Si. The formation of the oxide layer can cause the fin to oxidize. A solution to the oxidizing issue of the fin is to enclose the fin in a protective layer prior to the formation of the oxide layer. The protective layer can be comprised of, for example, SiN. However, a protective layer comprised of SiN causes a different defect in the fin. The protective layer has an inherent positive charge that attracts negative charges to the middle of sub active channel (or the fin that is enclosed by the oxide layer). This prevents punch through leakage by PTS implantation leading to degraded device performance. The present invention is directed to forming a dual layer liner to protect the fin from the shallow trench isolation fill step (e.g., oxidation defect) and to prevent the formation of a negative charge formation in the fin (charge defect). The first liner is comprised of, for example, SiO₂, where the first layer is deposited by the means of atomic layer deposition or a similar manner that will not cause the fin to oxidize. The first liner has a thickness in the range of about 2 to 5 nm. The first liner prevents the charge defect from forming in the fin. A second liner is formed on the first liner. The second liner can be comprised of, for example, SiN. The second liner has a thickness in the range of about 2 to 8 nm. The second liner prevents the oxidation of the fin from the formation of the shallow trench isolation layer.

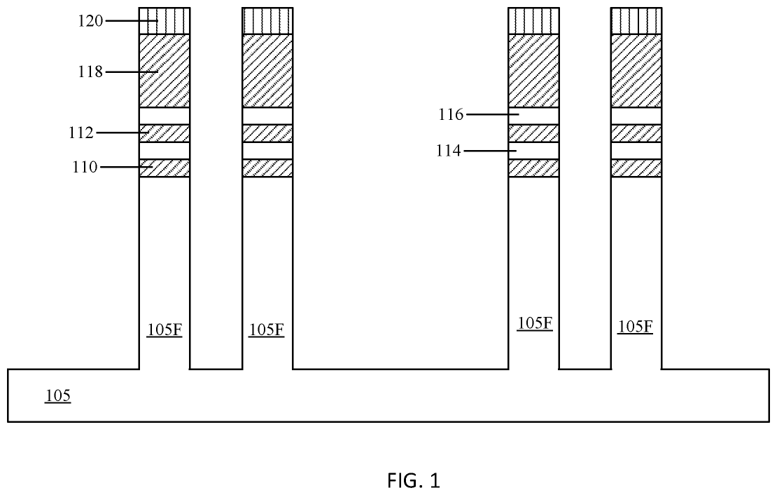

FIG. 1 illustrates a cross section of the forksheet device after initial processing to form the fins 105F, in accordance with the embodiment of the present invention. FIG. 1 illustrates a structure shown during an intermediate step of a method of fabricating a forksheet device, according to an embodiment of the invention.

FIG. 1 illustrates the nano stack of the forksheet device that includes a substrate 105, a plurality of fins 105F, a first and second sacrificial layer 110, 112, a first and second channel layer 114, 116, a sacrificial cap 118, and a hardmask 120.

The first and second sacrificial layers 110, 112 and the first and second channel layers 114, 116 are alternatively formed on top of the substrate 105.

The substrate 105 can be, for example, a material including, but not necessarily limited to, silicon (Si), silicon germanium (SiGe), Si: C (carbon doped silicon), carbon doped silicon germanium (SiGe: C), III-V, II-V compound semiconductor or another like semiconductor. In addition, multiple layers of semiconductor materials can be used as the semiconductor material of substrate 105. In some embodiments, substrate 105 includes both semiconductor materials and dielectric materials. The semiconductor substrate 105 may also comprise an organic semiconductor or a layered semiconductor such as, for example, Si/SiGe, a silicon-on-insulator or a SiGe-on-insulator. A portion or the entire semiconductor substrate 105 may also be comprised of an amorphous, polycrystalline, or monocrystalline. The semiconductor substrate 105 may be doped, undoped or contain doped regions and undoped regions therein.

The first and second sacrificial layers 110, 112 can be comprised of, for example, SiGe and the first and second channel layer 114, 116, can be comprised of, for example, Si. The present invention only illustrates two alternatively formed sacrificial layers 110, 112 and channel layers 114, 116, but this is only for illustrative purposes only. It is well within the skill level of one of ordinary skill in the art to increase the number of alternating layers (sacrificial layers 110, 112, and channel layers 114, 116). A sacrificial cap 118 is formed on top of the top channel layer (e.g., the second channel layer 116) and a hardmask 120 is formed on top of the sacrificial cap 118. The sacrificial cap 118 can be comprised of, for example, SiGe. The hardmask 120, the sacrificial cap 118, the first and second channel layers 114, 116, the first and second sacrificial layers 110, 112, and the substrate 105 are patterned to form a plurality of columns. The patterning of substrate 105 causes a plurality of fins 105F to be formed.

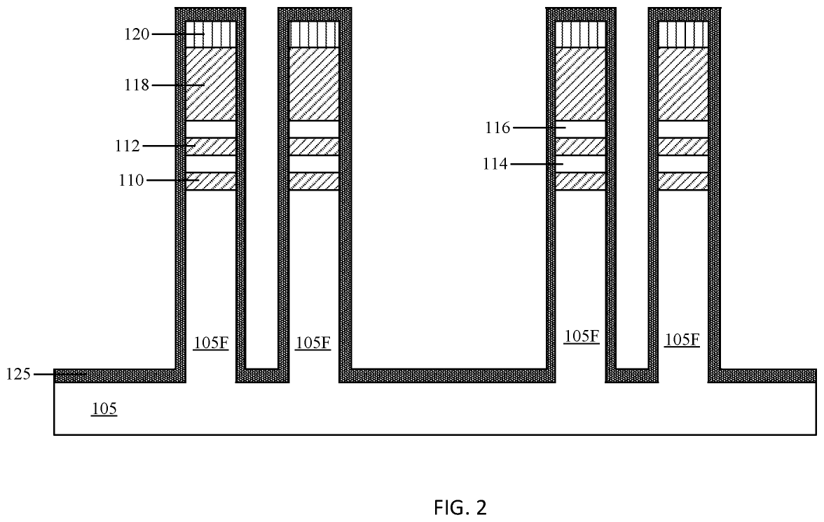

FIG. 2 illustrates a processing stage after formation of the first liner 125. The first liner 125 is formed on the exposed surfaces, meaning that the first liner 125 is formed on the substrate 105 and along the sidewalls of the each of the columns. The first liner 125 is formed by, for example, atomic layer deposition (ALD) or another suitable deposition process that will not cause the oxidation of the substrate 105 or the fins 105F. The first liner 125 can be comprised of an oxide, for example, SiO₂ and has a thickness in the range of about 2 to 5 nanometers. The first liner 125 protects the fin 105F from developing a negative charge from the second liner 130. The first liner 125 encloses each of the plurality of columns and is located on top of the trenches formed in substrate 105.

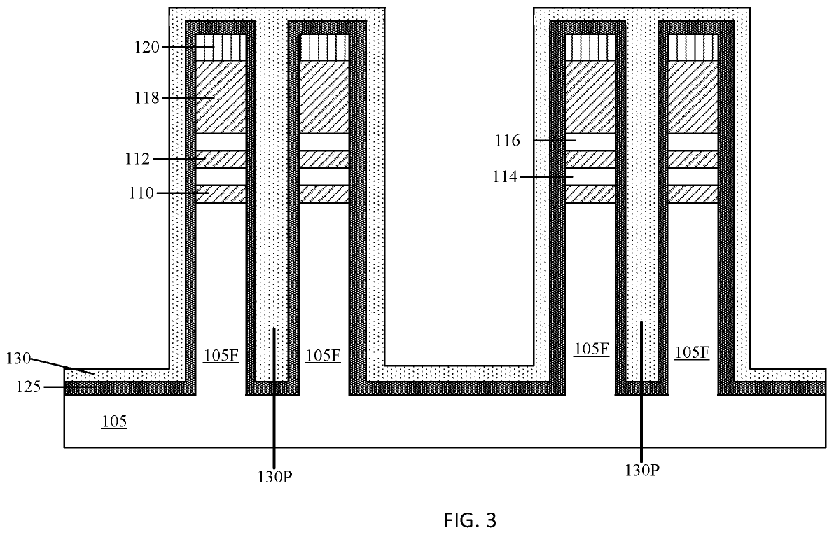

FIG. 3 illustrates a processing stage after formation of the second liner 130. The second liner 130 is located on top of the first liner 125. The second liner 130 can be comprised of a suitable barrier material, for example, SiN. The second liner 130 can have a thickness in the range of about 3 to 8 nanometers. The second liner 130 further fills the space between two adjacent columns forming a pillar made from the second liner 130, herein after this pillar of the second liner 130 will be referred to as pillar 130P. Pillar 130P is located between two adjacent fins 105F and pillar 130P extends to the top of the columns. The dimensions (e.g., thickness) of pillar 130P can vary when compared to the dimension (e.g., thickness of 3 to 8 nm) of the rest of the second liner 130. The thickness of the pillar 130P is a combined thickness of the second liner 130 that is formed on two adjacent surfaces of the first liner 125. Furthermore, pillar 130P does not have to be comprised of a solid piece of material but can include air gaps that are caused by the pinching off the opening at the top of the columns. The second liner 130, and the pillar 130P prevent the oxidation of the fins 105F and the channel layer 114, 116 during the formation of the shallow trench isolation layer 135 as described below.

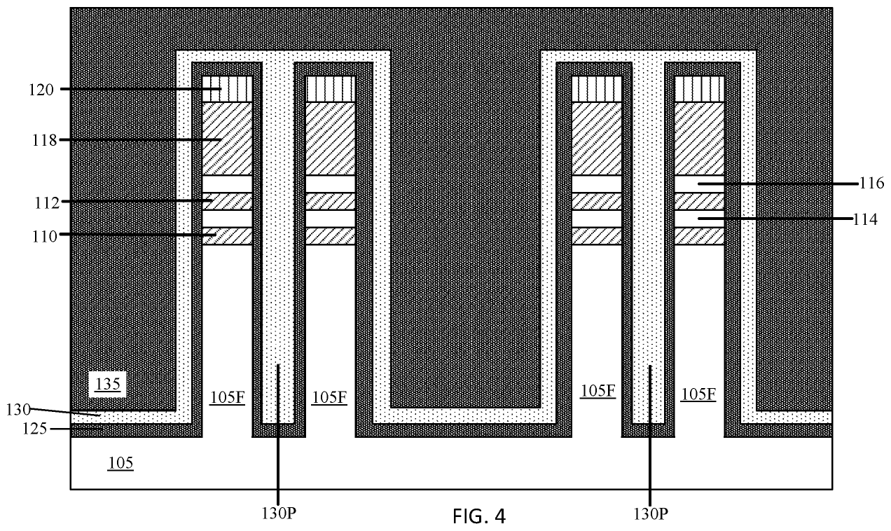

FIG. 4 illustrates a processing stage after formation of the shallow trench isolation layer 135. The shallow trench isolation layer 135 is formed on all the exposed surface to enclose the entire forksheet device. The shallow trench isolation layer 135 underwent a densification process, which would have oxide the fins 105 if they were not protected by the first liner 125 and the second liner 130. The shallow trench isolation layer 135 is comprised of an oxide material, for example, SiO₂ or another suitable oxide. The shallow trench isolation layer 135 can be comprised of the same material as the first liner 125 or it can be comprised of a different material. The first liner 125 is prevented from undergoing the densification process by the second liner 130. The second liner 130 and the first liner 125 protect the fins 105F from being oxidized by the processing stage that forms the shallow trench isolation layer 135.

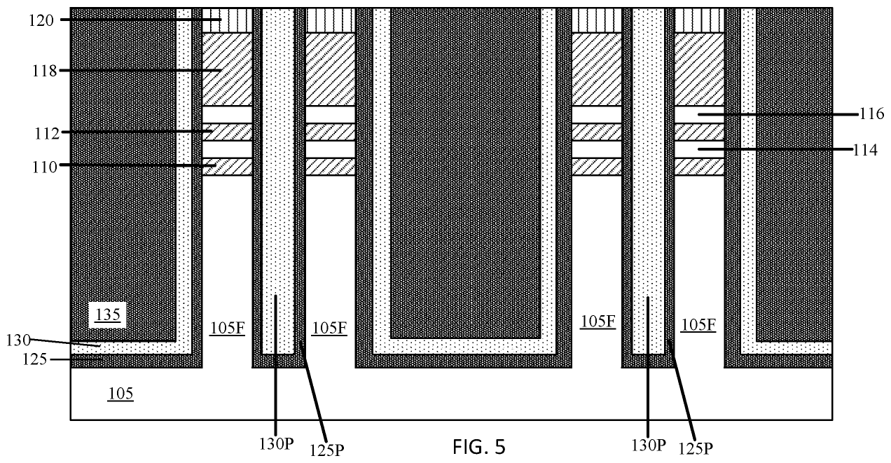

FIG. 5 illustrates a processing stage after the removal of excess materials. The height of the shallow trench isolation layer 135 is reduced by, for example, chemical mechanical planarization (CMP). The reduced height of the shallow trench isolation layer 135 exposes a top surface of the second liner 130 that is located on top of the columns. A second etching process, for example, a non-selective reactive ion etch, removes a top portion of the second liner 130 and a top portion of the first liner 125. The removal of these portions of the liners 125, 130 exposes the hardmask 120. Pillar 130P. Furthermore, the removal of the top portions of the liner 125, 130 causes the first pillar liner 125P and pillar 130P to be separated from the rest of the liner 125, 130. Therefore, the pillar 130P and the first pillar liner 125P are now independent components from the rest of the liners 125, 130.

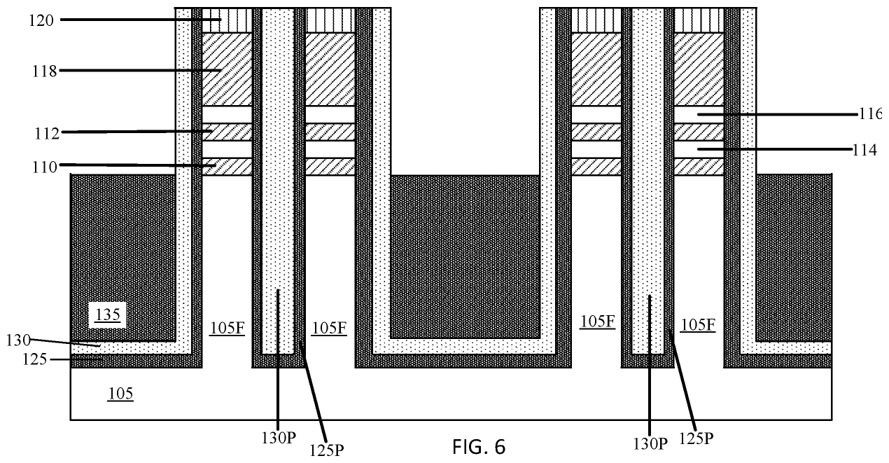

FIG. 6 illustrates a processing stage after the pulling down of the shallow trench isolation layer 135. The shallow trench isolation layer 135 is pulled down, where the height of the shallow trench isolation layer 135 so that it is lower than the first sacrificial layer 110. The top surface of the shallow trench isolation layer 135 is about at the same height of the fins 105F. The shallow trench isolation layer 135 is surrounded by the first liner 125 and the second liner 130. The first liner 125 and the second liner 130 are located beneath the shallow trench isolation layer and along the vertical sidewalls of the shallow trench isolation layer 135.

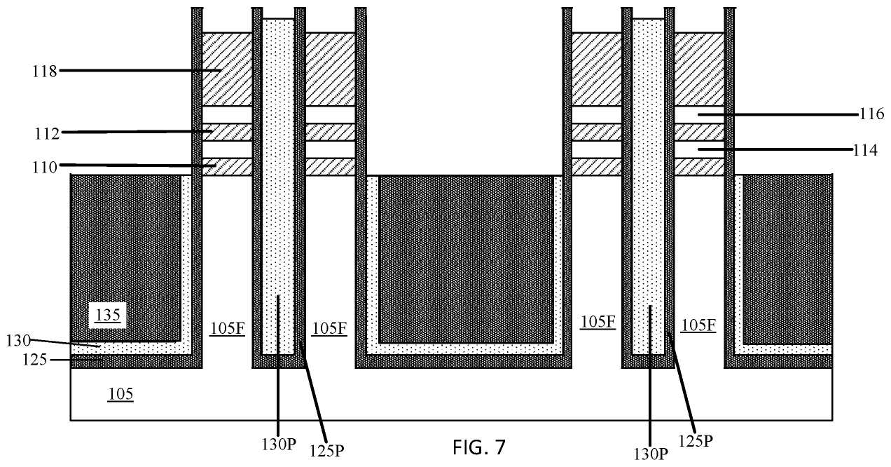

FIG. 7 illustrates a processing stage after pulling down of the second liner 130 and the removal of the hardmask 120. Portions of the second liner 130 that were exposed by the pull down of the shallow trench isolation layer 135 are removed and the hardmask 120 was removed. The pull down of the second liner 130 exposes a portion of the first liner 125 and the removal of the hardmask 120 exposes the top surface of the sacrificial cap 118. Pillar 130P is not significantly pulled down with the removal of the second liner 130.

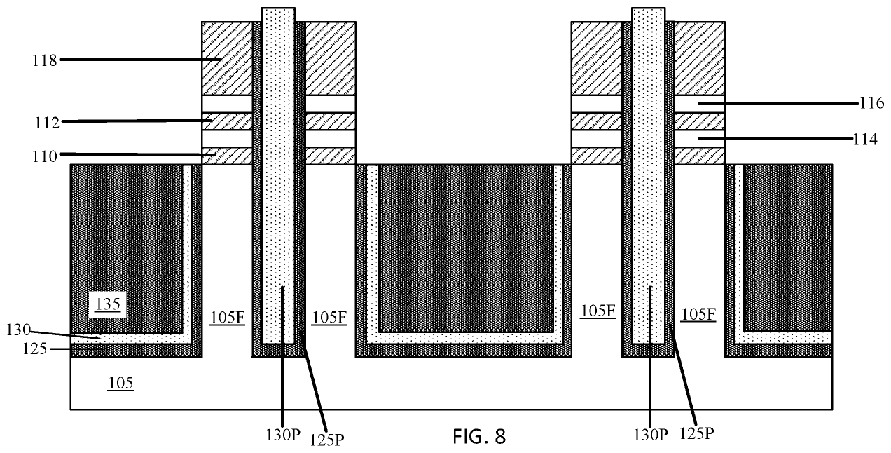

FIG. 8 illustrates a processing stage after pulling down of the first liner 125. The removal/pull down of the second liner 130 exposed a portion of the first liner 125. The exposed portion of the first liner 125 is removed, which exposes a side surface of the first and second sacrificial layers 110, 112, a side surface of the first and second channel layers 114, 116, and a side surface of the sacrificial cap 118. The exposed side surface is the side surface of the pillar 130P and the first pillar liner 125P. Therefore, the first and second sacrificial layers 110, 112, the first and second channel layers 114, 116, and the sacrificial cap 118 have a common side surface that is in contact with the first pillar liner 125P, while these layers have a common exposed side surface that is opposite surface that is in contact with the first pillar liner 125P.

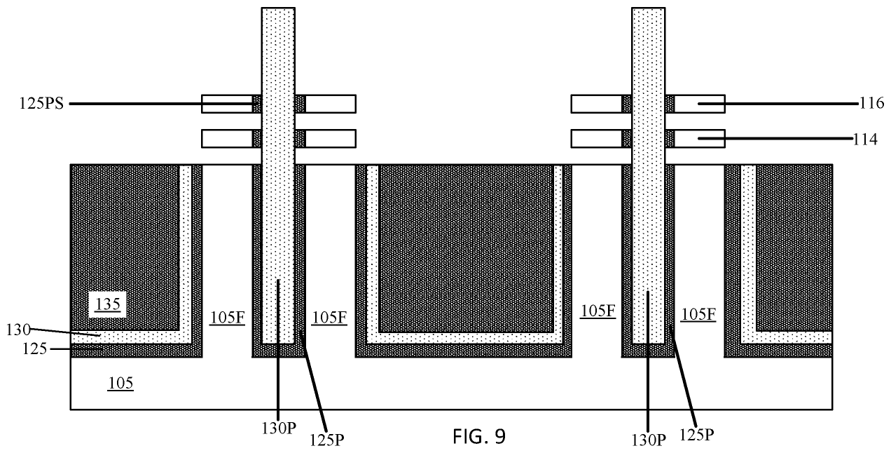

FIG. 9 illustrates a processing stage after removal of the sacrificial cap 118 and the first and second sacrificial layers 110, 112, and after a cleaning process that removes a portion of the first pillar liner 125P. The sacrificial cap 118, the first sacrificial layer 110, and the second sacrificial layer 112 are removed. The removal of these layers exposes portions of the first pillar liner 125P. The forksheet device undergoes a cleaning process the removes portions of the first pillar liner 125P. Segments of the first pillar liner 125PS remain after the cleaning process, where these segments of the first pillar liner 125PS are located between the first and second channel layer 114, 116 and pillar 130P.

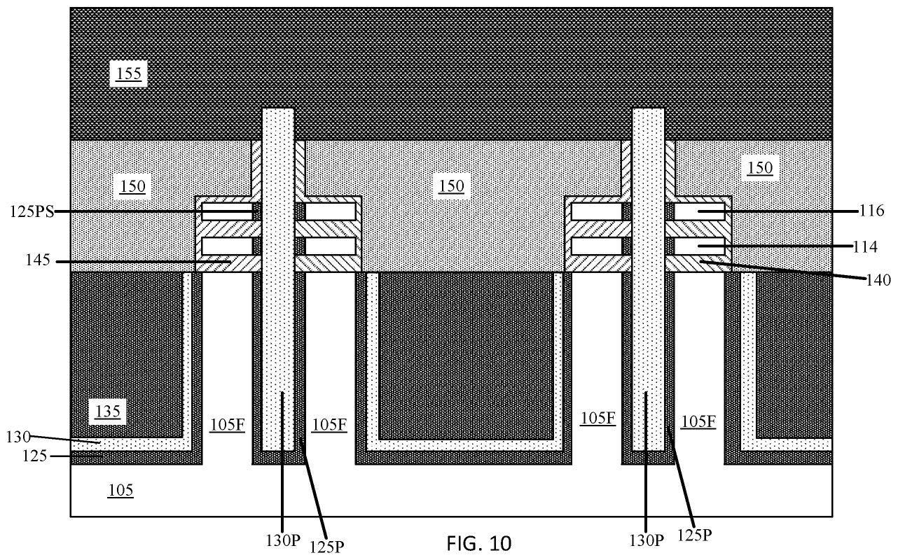

FIG. 10 illustrates a processing stage after formation of a first and second work function metal 140, 145, formation of the gate 150, and formation of an interlayer dielectric layer 155. A first work function metal 140, for example, a N-type work function metal, is formed around the channel layer 114, 116 located on a first side of pillar 130P. A second work function metal 145, for example, a P-type work function metal, is formed around the channel layer 114, 116 located on a second side of pillar 130P. The first and second work function metal 140, 145 surround their respective channel layer 114, 116 and the first second work function metal 140, 145 are in contact with the segments of the first pillar liner 125PS. The first and the second work function metal 140, 145 have a vertical segment that extends up the pillar 130P. Gate 150 is formed around the first and second work function metals 140, 145. Gate 150 can be comprised of, for example, a gate dielectric liner, such as high-k dielectric like HfO₂, ZrO₂, HfLₐOₓ, etc., and work function layers, such as TiN, TiAlC, TiC, etc., and conductive metal fills, like W. An interlayer dielectric layer 155 is formed on top of gate 150, the first and second work function metal 140, 145. The interlayer dielectric layer 155 can further surround the tip or a top segment of pillar 130P. The illustrated cross section does not illustrate any contacts or other components that are necessary for a forksheet device. The illustrated cross section is only a small slice of the device that is illustrated but it well within the skills of one of ordinary skill in the art to have attached all the necessary components, for example, contacts, source/drains, etc.

A microelectronic structure that includes a forksheet device that includes a first fin 105F and a second fin 105F and plurality of channel layers 114, 116 located above the first and second fins 105F. A first liner 125 located along each sidewall of the first and second fin 105F and a second liner 130 located along the surface of the first liner 125. The first liner 125 isolates the first and second fin 105F from electrically interacting with the second liner 130. A shallow trench isolation layer 135 located adjacent to the second liner 130.

A pillar 130P located between the first and second fins 105F, wherein the pillar 130P extends from the bottom of the first and second fins 105 to above the plurality of channel layers 114, 116. Segments of the first liner 125PS located directly adjacent to each of the plurality of channel layers 114, 116. The segments of the first liner 125PS are located between the pillar 130P and each of the plurality of channel layers 114, 116. A first work function metal 140 surrounds the plurality of channel layers 114, 116 on a first side of the pillar 130P. A second work function metal 145 surrounds the plurality of channel layers 114, 116 on a second side of the pillar 130P. The first work function metal 140 is in direct contact with the first side of the pillar 130P, and the second work function metal 145 is in direct contact with the second side of the pillar 130P. The first work function metal 145 is in direct contact with the segments of the first liner 125PS located directly adjacent to each of the plurality of channel layers 114, 116 on the first side of the pillar 130P. The second work function metal 145 is in direct contact with the segments of the first liner 125PS located directly adjacent to each of the plurality of channel layers 114, 116 on the second side of the pillar 130P. The first liner 125P extends under a bottom surface of the pillar 130P. An interlayer dielectric layer 155 located above the plurality of channel layers 114, 116 and the pillar 130P extends into the interlayer dielectric layer 155.

A microelectronic structure that includes a forksheet device that includes a first fin 105F and a second fin 105F and plurality of channel layers 114, 116 located above the first and second fins 105F. A first liner 125 located along each sidewall of the first and second fin 105F and a second liner 130 located along the surface of the first liner 125. The first liner 125 isolates the first and second fin 105F from electrically interacting with the second liner 130. A shallow trench isolation layer 135 located adjacent to the second liner 130. A shallow trench isolation layer 135 located adjacent to the second liner 130 and the first liner 125 and the second liner 130 extends under a bottom surface of the shallow trench isolation layer 135.

A pillar 130P located between the first and second fins 105F, wherein the pillar 130P extends from the bottom of the first and second fins 105 to above the plurality of channel layers 114, 116. Segments of the first liner 125PS located directly adjacent to each of the plurality of channel layers 114, 116. The segments of the first liner 125PS are located between the pillar 130P and each of the plurality of channel layers 114, 116. A first work function metal 140 surrounds the plurality of channel layers 114, 116 on a first side of the pillar 130P. A second work function metal 145 surrounds the plurality of channel layers 114, 116 on a second side of the pillar 130P. The first work function metal 140 is in direct contact with the first side of the pillar 130P, and the second work function metal 145 is in direct contact with the second side of the pillar 130P. The first work function metal 145 is in direct contact with the segments of the first liner 125PS located directly adjacent to each of the plurality of channel layers 114, 116 on the first side of the pillar 130P. The second work function metal 145 is in direct contact with the segments of the first liner 125PS located directly adjacent to each of the plurality of channel layers 114, 116 on the second side of the pillar 130P. The first liner 125P extends under a bottom surface of the pillar 130P. An interlayer dielectric layer 155 located above the plurality of channel layers 114, 116 and the pillar 130P extends into the interlayer dielectric layer 155.

A microelectronic structure that includes a forksheet device that includes a first fin 105F and a second fin 105F and plurality of channel layers 114, 116 located above the first and second fins 105F. A first liner 125 located along each sidewall of the first and second fin 105F. The first liner 125 has a thickness in the range of about 2 to 5 nanometers. A second liner 130 located along the surface of the first liner 125. The second liner has a thickness in the range of about 2 to 8 nanometers. The first liner 125 isolates the first and second fin 105F from electrically interacting with the second liner 130. A shallow trench isolation layer 135 located adjacent to the second liner 130. A shallow trench isolation layer 135 located adjacent to the second liner 130 and the first liner 125 and the second liner 130 extends under a bottom surface of the shallow trench isolation layer 135.

The first liner 125 is comprised of SiO₂, and the second liner 130 is comprised of SiN.

While the invention has been shown and described with reference to certain exemplary embodiments thereof, it will be understood by those skilled in the art that various changes in form and details may be made therein without departing from the spirit and scope of the present invention as defined by the appended claims and their equivalents.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the one or more embodiment, the practical application or technical improvement over technologies found in the marketplace, or to enable others of ordinary skill in the art to understand the embodiments disclosed herein.

What is claimed is:

1. A microelectronic structure comprising:
a forksheet device that includes a first fin and a second fin and plurality of channel layers located above the first and second fin;
a first liner located along each sidewall of the first and second fin;
a second liner located along a surface of the first liner, wherein the first liner isolates the first and second fin from electrically interacting with the second liner; and
a shallow trench isolation layer located adjacent to the second liner.

2. The microelectronic structure of claim 1, further comprising:
a pillar located between the first and second fins, wherein the pillar extends from the bottom of the first and second fins to above the plurality of channel layers.

3. The microelectronic structure of claim 2, further comprising:
segments of the first liner located directly adjacent to each of the plurality of channel layers.

4. The microelectronic structure of claim 3, wherein the segments of the first liner are located between the pillar and each of the plurality of channel layers.

5. The microelectronic structure of claim 4, further comprising:
a first work function metal surrounds the plurality of channel layers on a first side of the pillar; and
a second work function metal surrounds the plurality of channel layers on a second side of the pillar.

6. The microelectronic structure of claim 5, wherein the first work function metal is in direct contact with the first side of the pillar, and wherein the second work function metal is in direct contact with the second side of the pillar.

7. The microelectronic structure of claim 6, wherein the first work function metal is in direct contact with the segments of the first liner located directly adjacent to each of the plurality of channel layers on the first side of the pillar, and wherein the second work function metal is in direct contact with the segments of the first liner located directly adjacent to each of the plurality of channel layers on the second side of the pillar.

8. The microelectronic structure of claim 7, wherein the first liner extends under a bottom surface of the pillar.

9. The microelectronic structure of claim 8, further comprising:
an interlayer dielectric layer located above the plurality of channel layers, wherein the pillar extends into the interlayer dielectric layer.

10. A microelectronic structure comprising:
a forksheet device that includes a first fin and a second fin and plurality of channel layers located above the first and second fin;
a first liner located along each sidewall of the first and second fin;
a second liner located along a surface of the first liner, wherein the first liner isolates the first and second fin from electrically interacting with the second liner; and
a shallow trench isolation layer located adjacent to the second liner, wherein the first liner and the second liner extends under a bottom surface of the shallow trench isolation layer.

11. The microelectronic structure of claim 10, further comprising:
a pillar located between the first and second fins, wherein the pillar extends from the bottom of the first and second fins to above the plurality of channel layers.

12. The microelectronic structure of claim 11, further comprising:
segments of the first liner located directly adjacent to each of the plurality of channel layers.

13. The microelectronic structure of claim 12, wherein the segments of the first liner are located between the pillar and each of the plurality of channel layers.

14. The microelectronic structure of claim 13, further comprising:
a first work function metal surrounds the plurality of channel layers on a first side of the pillar; and
a second work function metal surrounds the plurality of channel layers on a second side of the pillar.

15. The microelectronic structure of claim 14, wherein the first work function metal is in direct contact with the first side of the pillar, and wherein the second work function metal is in direct contact with the second side of the pillar.

16. The microelectronic structure of claim 15, wherein the first work function metal is in direct contact with the segments of the first liner located directly adjacent to each of the plurality of channel layers on the first side of the pillar, and wherein the second work function metal is in direct contact with the segments of the first liner located directly adjacent to each of the plurality of channel layers on the second side of the pillar.

17. The microelectronic structure of claim 16, wherein the first liner extends under a bottom surface of the pillar.

18. The microelectronic structure of claim 17, further comprising:
an interlayer dielectric layer located above the plurality of channel layers, wherein the pillar extends into the interlayer dielectric layer.

19. A microelectronic structure comprising:
a forksheet device that includes a first fin and a second fin and plurality of channel layers located above the first and second fin;
a first liner located along each sidewall of the first and second fin, wherein the first liner has a thickness in the range of about 2 to 5 nanometers;
a second liner located along a surface of the first liner, wherein the first liner isolates the first and second fin from electrically interacting with the second liner, wherein the second liner has a thickness in the range of about 2 to 8 nanometers; and
a shallow trench isolation layer located adjacent to the second liner, wherein the first liner and the second liner extends under a bottom surface of the shallow trench isolation layer.

20. The microelectronic structure of claim 19, wherein the first liner is comprised of SiO₂, and wherein the second liner is comprised of SiN.
